(19) United States
(12) Patent Application Publication
(10) Pub. No.: US 2025/0358942 A1
(43) Pub. Date: Nov. 20, 2025

(54) FIXING STRUCTURE FOR FACEPLATE VENTILATION SCREEN OF POWER SUPPLY UNIT

(71) Applicant: Hong Liu Limited Company, Taichung (TW)

(72) Inventor: Mu-Chun LIN, Taichung (TW)

(21) Appl. No.: 18/663,820

(22) Filed: May 14, 2024

(51) Int. Cl. H05K 5/02

(52) U.S. Cl. CPC H05K 5/0213

(57) ABSTRACT

A fixing structure for a faceplate ventilation screen of a power supply unit includes a faceplate body and a ventilation screen. The faceplate body has a top end and a bottom end each provided with an extension plate transversely extending from an inner side thereof. The faceplate body further has an opening. The extension plates have opposite inner sides each provided with a positioning flange extending inwardly at a location close to the opening. A positioning groove is formed between the positioning flange and the faceplate body. The ventilation screen is disposed on the opening. The ventilation screen has a curved profile corresponding to that of the faceplate body. The ventilation screen is flexible and deformable. The ventilation screen is attached and secured to the faceplate body by curving the ventilation screen for top and bottom ends of the ventilation screen to be placed into the respective positioning grooves.

### FIELD OF THE INVENTION

The present invention relates to a fixing structure, and more particularly, to a fixing structure for a faceplate ventilation screen of an AC/DC power supply unit.

### BACKGROUND OF THE INVENTION

In general, when a power supply unit carries out AC and DC power supply conversion, operation of the electronic parts in the power supply unit will produce high temperature. In order to prevent the electronic parts of a power supply unit from being damaged by excessively high temperature produced in the power supply unit, cooling fins and heat-dissipating fans are provided inside the power supply unit, and the faceplate of the power supply unit has at least one opening. A ventilation screen is mounted on the opening for exhausting high temperature out of the power supply unit through circulation, so as to enhance the effect of heat dissipation for the power supply unit.

The ventilation screen of a conventional power supply unit is threadedly connected to the casing or the faceplate of the power supply unit; therefore, the casing and the ventilation screen of the power supply unit have to be bored with a plurality of locking holes so that the ventilation screen can be firmly fixed on the casing of the power supply unit by means of locking members. This spoils esthetic appearance of a power supply unit. Besides, the installation of the ventilation screen is complicated.

As disclosed in U.S. Pat. No. 8,410,362, a fixing structure for the faceplate ventilation screen of a power supply unit includes a faceplate body and at least one ventilation screen. The faceplate body has an inner side formed with at least two extension portions protruding out vertically in the same direction. The extension portions have opposite inner sides respectively provided with a positioning member extending oppositely at a location adjacent to the faceplate body. The positioning members are parallel to the faceplate body, and a predetermined gap is formed between the positioning members and the faceplate body for receiving two ends of the ventilation screen. Thus, the positioning members can be deformed by applying an external force toward the faceplate body for the ventilation screen to be fixed on the faceplate body, without using locking members. The process of installing the ventilation screen is simplified.

However, since the ventilation screen is made of a flat metal plate, it lacks flexibility. A wider predetermined gap is required to facilitate the installation of the ventilation screen. Then, an external force is applied to the positioning members to be deformed toward the faceplate body and pushed on the ventilation screen to firmly fix the ventilation screen on the faceplate body, thereby preventing the ventilation screen from loosening or falling off. This installation structure and method leads to an additional installation process.

Accordingly, the inventor of the present invention has devoted himself based on his many years of practical experiences to solve these problems.

### SUMMARY OF THE INVENTION

The primary object of the present invention is to provide a fixing structure for a faceplate ventilation screen of a power supply unit, which simplifies the installation of a ventilation screen and is aesthetically pleasing to the eye.

In order to achieve the foregoing object, the fixing structure provided by the present invention comprises a faceplate body and at least one ventilation screen. The faceplate body has a curved profile. The faceplate body has a top end and a bottom end. The top end and the bottom end each have an extension plate transversely extending from an inner side thereof. The faceplate body further has at least one opening. The extension plates of the top end and the bottom end of the faceplate body have opposite inner sides each provided with a positioning flange extending inwardly at a location close to the opening. A positioning groove is formed between the positioning flange and the faceplate body. The ventilation screen is disposed on the opening and corresponds in shape to the opening. The ventilation screen has a plurality of ventilation holes. The ventilation screen has a curved profile corresponding to the faceplate body.

The ventilation screen is flexible and deformable. The ventilation screen is secured to the faceplate body by curving the ventilation screen for top and bottom ends of the ventilation screen to be placed into the respective positioning grooves.

### BRIEF DESCRIPTION OF THE DRAWINGS

FIG. 1 is an exploded view of a preferred embodiment of the present invention;

FIG. 2 is another exploded view of the preferred embodiment of the present invention;

FIG. 3 is a perspective view of the preferred embodiment of the present invention;

FIG. 4 is a front view of the preferred embodiment of the present invention; and

FIG. 5 is a side sectional view of the preferred embodiment of the present invention.

### DETAILED DESCRIPTION OF THE PREFERRED EMBODIMENTS

Embodiments of the present invention will now be described, by way of example only, with reference to the accompanying drawings.

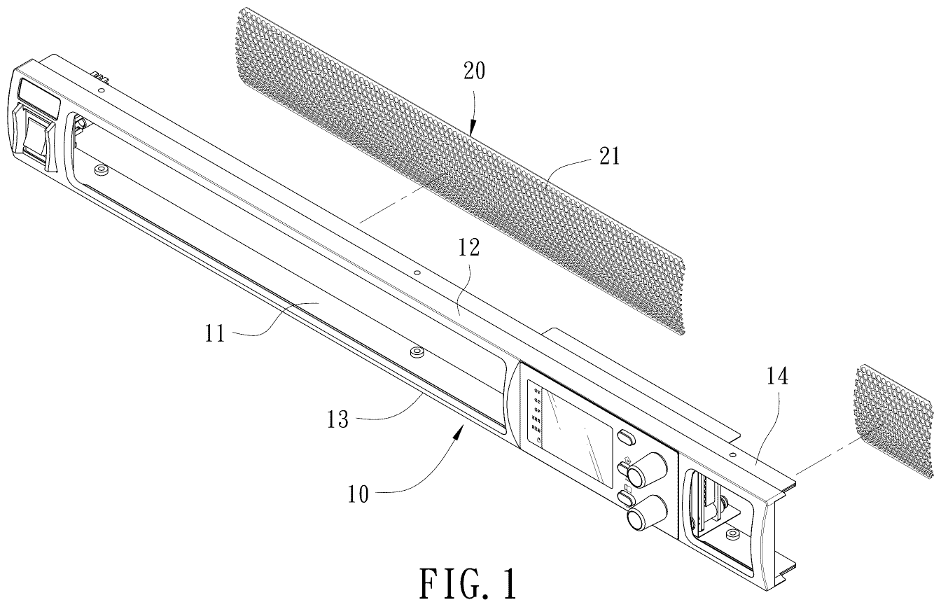

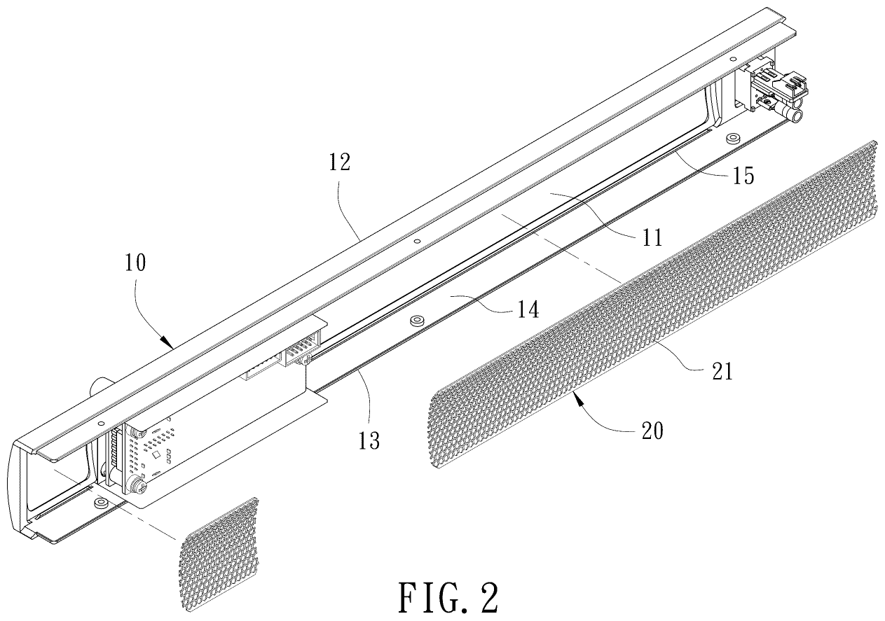

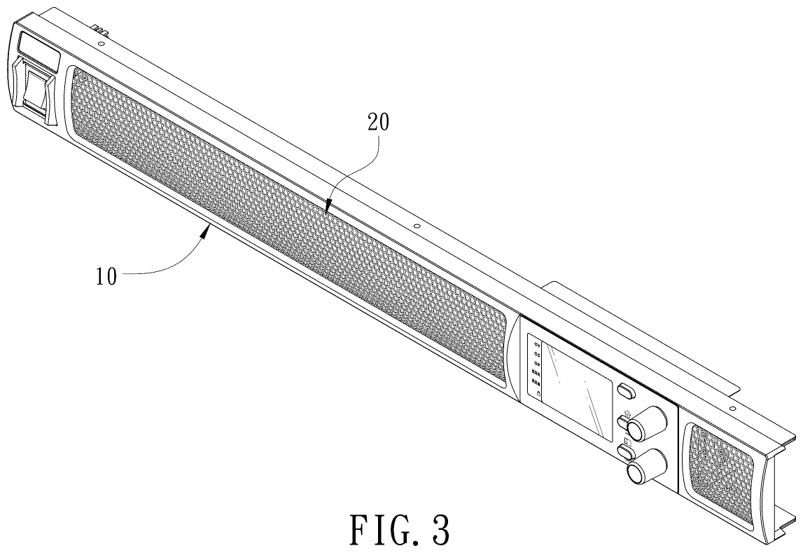

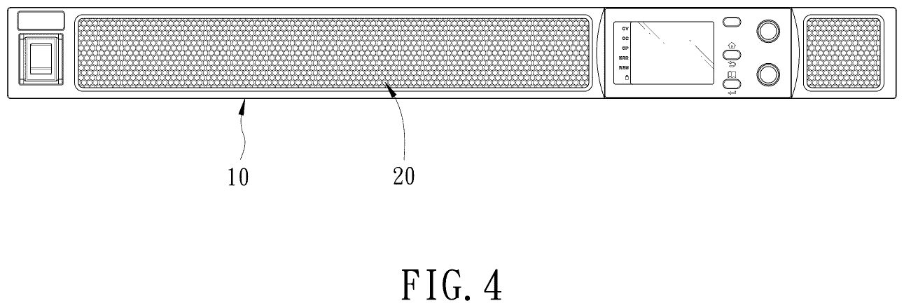

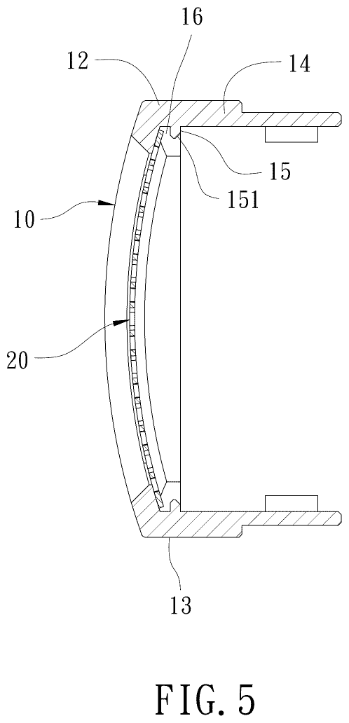

As shown in FIG. 1 through FIG. 5, the present invention discloses a fixing structure for a faceplate ventilation screen of a power supply unit, comprising a faceplate body 10 and two ventilation screens 20.

The faceplate body 10 is generally rectangular in shape and has a curved profile. The faceplate body 10 has two rectangular openings 11 and two ends defined as a top end 12 and a bottom end 13. The top end 12 and the bottom end 13 of the faceplate body 10 each have an extension plate 14 perpendicularly extending from the inner side of the faceplate body 10. The extension plates 14 of the top end 12 and the bottom end 13 of the faceplate body 10 have opposite inner sides each provided with a positioning flange 15 extending inwardly at a location close to the opening 11. A guide slope 151 is formed on either side of the distal end of the positioning flange 15, so the positing flange 15 has a tapered profile. A positioning groove 16 is formed between the positioning flange 15 and the faceplate body 10.

The ventilation screens 20 are disposed on the respective openings 11 and correspond in shape to the respective openings 11. The ventilation screen 20 has a plurality of ventilation holes 21. The ventilation holes 21 are in a honeycomb shape. The ventilation screen 20 also has a curved profile corresponding to the faceplate body 10. The ventilation screen 20 is made of a metal material with flexibility, so that the ventilation screen 20 is flexible and deformable. Through the flexibility of the ventilation screen 20, the ventilation screen 20 is secured to the faceplate body 10 by placing the top and bottom ends of the ventilation screen 20 into the respective positioning grooves 16.

In order to further understand the structural features, the technical means and the expected effects of the present invention, the assembly and achieved effects of the present invention are described hereinafter.

When the ventilation screen 20 is to be mounted on the faceplate body 10, one end of the ventilation screen 20 is first placed into the corresponding positioning groove 16 of the faceplate body 10, and then an external force is applied to the ventilation screen 20 to curve and deform the ventilation screen 20 until the other end of the ventilation screen 20 crosses the corresponding positioning flange 15 to be placed into the corresponding positioning groove 16. Because the guide slope 151 is formed on either side of the distal end of the positioning flange 15, it is easy for the top and bottom ends of the ventilation screen 20 to be placed into the respective positioning grooves 16. When no more external force is applied to the ventilation screen 20, the top and bottom ends of the ventilation screen 20 are inserted into the respective positioning grooves 16 due to the flexible restoring force of the ventilation screen 20, such that the ventilation screen 20 is attached and secured to the inner side wall of the faceplate body 10. In this way, the installation of the ventilation screen 20 is completed.

The features and the expected effects of the present invention are described below.

In the fixing structure provided by the present invention, the ventilation screen 20 is designed in a curved shape, so the ventilation screen 20 has a certain degree of flexibility. When the top and bottom ends of the ventilation screen 20 are to be mounted in the positioning grooves 16 formed between the faceplate body 10 and the respective positioning flanges 15, an external force will be applied to the ventilation screen 20 to curve and deform the ventilation screen 20, such that the top and bottom ends of the ventilation screen 20 can be easily placed into the respective positioning grooves 16 of the faceplate body 10. When the external force disappears, the top and bottom ends of the ventilation screen 20 will be inserted into the respective positioning grooves 16 due to the flexible restoring force of the ventilation screen 20, and the ventilation screen 20 will be attached and secured to the inner side wall of the faceplate body 10, without using bolts. The installation of the ventilation screen 20 is simplified. Since both the faceplate body 10 and the ventilation scree 20 are designed in a curved shape, they are aesthetically pleasing to the eye.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A fixing structure for a faceplate ventilation screen of a power supply unit, comprising:
a faceplate body, having a curved profile, the faceplate body having a top end and a bottom end, the top end and the bottom end each having an extension plate transversely extending from an inner side thereof, the faceplate body further having at least one opening, the extension plates of the top end and the bottom end of the faceplate body having opposite inner sides each provided with a positioning flange extending inwardly at a location close to the opening, a positioning groove being formed between the positioning flange and the faceplate body;
at least one ventilation screen, disposed on the opening and corresponding in shape to the opening, the ventilation screen having a plurality of ventilation holes, the ventilation screen having a curved profile corresponding to the faceplate body, the ventilation screen being flexible and deformable, the ventilation screen being secured to the faceplate body by curving the ventilation screen for top and bottom ends of the ventilation screen to be placed into the respective positioning grooves.

2. The fixing structure as claimed in claim 1, wherein a guide slope is formed on either side of a distal end of the positioning flange, and the positing flange has a tapered profile for the top and bottom ends of the ventilation screen to be placed into the respective positioning grooves easily.

3. The fixing structure as claimed in claim 1, wherein the opening has a rectangular shape.

4. The fixing structure as claimed in claim 1, wherein the ventilation screen is made of a metal material with flexibility.

5. The fixing structure as claimed in claim 1, wherein the ventilation holes are in a honeycomb shape.
